(19) United States
(12) Patent Application Publication
(10) Pub. No.: US 2026/0239525 A1
(43) Pub. Date: Aug. 13, 2026

(54) HEAT DISSIPATION ASSEMBLY, MOTHERBOARD MODULE AND ELECTRONIC DEVICE

(71) Applicant: Wiwynn Corporation, New Taipei City (TW)

(72) Inventors: Tsung-Yi Chen, New Taipei City (TW); Hao-Jhan Hong, New Taipei City (TW); Yi Cheng, New Taipei City (TW); WEN AN CHEN, New Taipei City (TW)

(21) Appl. No.: 19/318,562

(22) Filed: Sep. 4, 2025

(30) Foreign Application Priority Data
Feb. 12, 2025 (TW) 114105174

(51) Int. Cl. H05K 1/02; H05K 7/14; H05K 7/20

(52) U.S. Cl. CPC H05K 1/0203; H05K 7/1427; H05K 7/20236; H05K 7/2029; H05K 2201/066; H05K 2201/10212

(57) ABSTRACT

A motherboard module includes a motherboard, a thermal interface material and a heat dissipation assembly. The motherboard includes a circuit board, a heat source and on-board components, the heat source and the on-board components are disposed on the circuit board, and the on-board components are located around the heat source. The heat dissipation assembly includes a heat dissipation device and an annular insulation component. The heat dissipation device has a thermally coupling surface and a joint surface, the thermally coupling surface is thermally coupled to the heat source of the motherboard via the thermal interface material, and the joint surface is located around the thermally coupling surface. The annular insulation component is fixed to the joint surface and contacts the on-board components located around the heat source. The annular insulation component surrounds and limits the thermal interface material to separate the thermal interface material from the on-board components.

### CROSS-REFERENCE TO RELATED APPLICATIONS

This non-provisional application claims priority under 35 U.S.C. § 119(a) on Patent Application No(s). 114105174filed in Taiwan, R.O.C. on February 12th, 2025, the entire contents of which are hereby incorporated by reference.

### TECHNICAL FIELD

The disclosure relates to a heat dissipation assembly, a motherboard module and an electronic device.

### BACKGROUND

Liquid metal is an emerging thermal interface material in recent years, known for its relatively high thermal conductivity. Due to high conductivity and fluidity of the liquid metal, if proper protective measures are not in place, the liquid metal may flow from a chip and comes into contact surrounding electronic components, causing damage.

To prevent the flowing of liquid metal, a common solution is to apply resin around the chip. This not only protects the surrounding components but also forms a barrier that can prevent the liquid metal from flowing out of the chip area. Then, by installing a heat dissipation module, the liquid metal can be sealed between the chip and the heat dissipation module.

Although the resin barrier can reduce the possibility of the flowing of the liquid metal to the surrounding components, if the surface smoothness of the resin barrier is reduced due to uneven surfaces around the chip during the coating of the resin barrier, it may result in insufficient sealing between the resin barrier and the heat dissipation module, allowing the liquid metal to pass through small gaps. In light of this, how to solve the aforementioned issue is one of the topics in this field.

### SUMMARY

One embodiment of the disclosure provides a motherboard module. The motherboard module includes a motherboard, a thermal interface material and a heat dissipation assembly. The motherboard includes a circuit board, a heat source and a plurality of on-board components, the heat source and the on-board components are disposed on the circuit board, and the on-board components are located around the heat source. The heat dissipation assembly includes a heat dissipation device and an annular insulation component. The heat dissipation device has a thermally coupling surface and a joint surface, the thermally coupling surface is thermally coupled to the heat source of the motherboard via the thermal interface material, and the joint surface is located around the thermally coupling surface. The annular insulation component is fixed to the joint surface and configured to contact the on-board components located around the heat source of the motherboard. The annular insulation component surrounds and limits the thermal interface material to separate the thermal interface material from the on-board components.

Another embodiment of the disclosure provides a heat dissipation assembly. The heat dissipation assembly is configured to be thermally coupled to a heat source of a motherboard via a thermal interface material. The heat dissipation assembly includes a heat dissipation device and an annular insulation component. The heat dissipation device has a thermally coupling surface and a joint surface. The thermally coupling surface is configured to be thermally coupled to the heat source of the motherboard via the thermal interface material, and the joint surface is located around the thermally coupling surface. The annular insulation component is fixed to the joint surface and configured to contact a plurality of on-board components located around the heat source of the motherboard. The annular insulation component is configured to surround and limit the thermal interface material to separate the thermal interface material from the on-board components.

Still another embodiment of the disclosure provides an electronic device. The electronic device includes an accommodation assembly and at least one motherboard module. The motherboard module is disposed in the accommodation assembly and includes a motherboard, a thermal interface material and a heat dissipation assembly. The motherboard includes a circuit board, a heat source and a plurality of on-board components. The heat source and the on-board components are disposed on the circuit board, and the on-board components are located around the heat source. The heat dissipation assembly includes a heat dissipation device and an annular insulation component. The heat dissipation device has a thermally coupling surface and a joint surface. The thermally coupling surface is thermally coupled to the heat source of the motherboard via the thermal interface material, and the joint surface is located around the thermally coupling surface. The annular insulation component is fixed to the joint surface and configured to contact the on-board components located around the heat source of the motherboard. The annular insulation component surrounds and limits the thermal interface material to separate the thermal interface material from the on-board components.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a partial cross-sectional view of an electronic device according to some embodiments of the disclosure;

FIG. 2 is a partial exploded view of a motherboard module according to some embodiments of the disclosure;

FIG. 3 shows a heat dissipation assembly is placed on a motherboard of a motherboard module according to some embodiments of the disclosure;

FIG. 4 shows a thermal interface material flows after a heat dissipation assembly placed on a motherboard is pressed downward according to some embodiments of the disclosure;

FIG. 5 is a cross-sectional view of a motherboard module according to some embodiments of the disclosure; and

FIG. 6 is a partial cross-sectional view of an electronic device according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

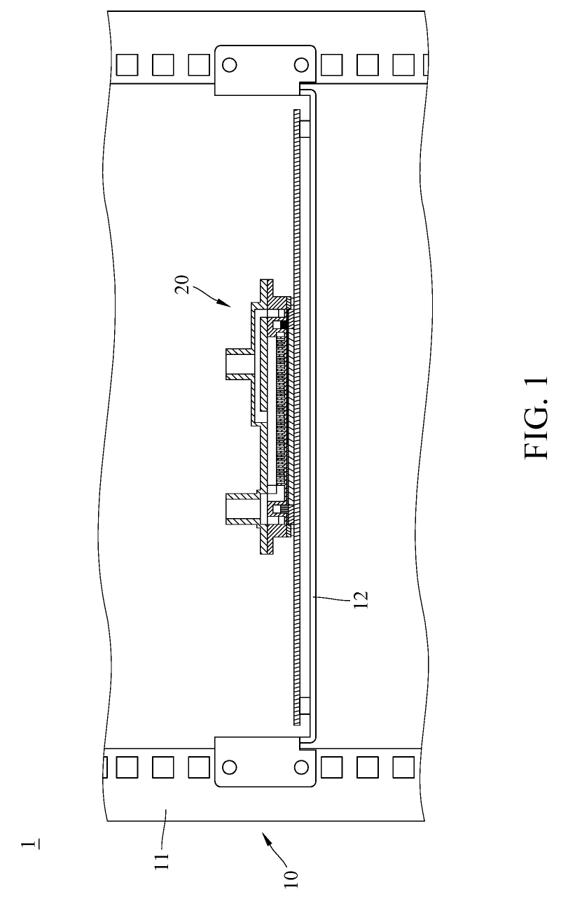

Referring to FIG. 1, FIG. 1 is a partial cross-sectional view of an electronic device 1 according to some embodiments of the disclosure. The structural features of FIG. 1 can be applied to other embodiments of the disclosure. The electronic device 1 includes an accommodation assembly 10 and at least one motherboard module 20. The motherboard module 20 is disposed in the accommodation assembly 10.

In some embodiments, the accommodation assembly 10 includes a rack 11 and a support component 12. The support component 12, for example, is a tray or a bracket, and the support component 12 is fixed in the rack 11. The motherboard module 20 is disposed on the support component 12. In other words, the motherboard module 20 is accommodated in the rack 11 via the support component 12.

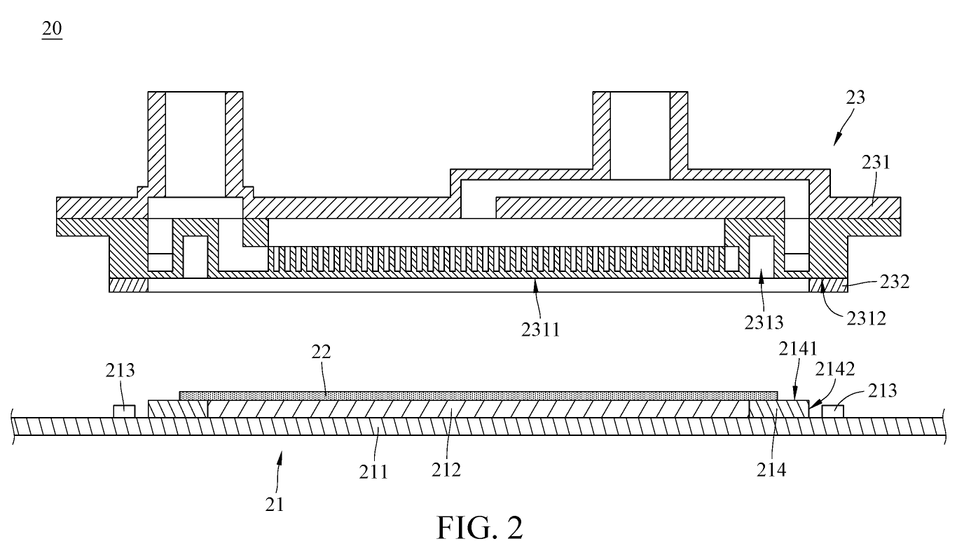

Referring to FIG. 2, FIG. 2 is a partial exploded view of a motherboard module 20 according to some embodiments of the disclosure. The structural features of FIG. 2 can be applied to other embodiments of the disclosure.

The motherboard module 20 includes a motherboard 21, a thermal interface material 22 and a heat dissipation assembly 23. The motherboard 21 includes a circuit board 211, a heat source 212 and a plurality of on-board components 213. The heat source 212 and the on-board components 213 are disposed on the circuit board 211, and the on-board components 213 are located around the heat source 212. The heat dissipation assembly 23 includes a heat dissipation device 231 and an annular insulation component 232. The heat dissipation device 231 has a thermally coupling surface 2311 and a joint surface 2312. The thermally coupling surface 2311 is thermally coupled to the heat source 212 of the motherboard 21 via the thermal interface material 22, and the joint surface 2312 is located around the thermally coupling surface 2311. The annular insulation component 232 is fixed to the joint surface 2312 and is configured to contact the on-board components 213 around the heat source 212 of the motherboard 21. The annular insulation component 232 surrounds and limits the thermal interface material 22 to separate the thermal interface material 22 from the on-board components 213.

In some embodiments, the heat source 212 of the motherboard 21 may be a central processing unit (CPU) or a graphics processing unit (GPU). In some embodiments, the on-board components 213 may be electronic components other than the CPU or the GPU, such as capacitors.

In some embodiments, the motherboard 21 may further include an annular frame 214. The annular frame 214 is disposed on the circuit board 211. The annular frame 214 is in contact with an outer edge of the heat source 212 and located between the heat source 212 and the on-board components 213. The annular frame 214 has an upper surface 2141 and a side surface 2142 located adjacent to each other. The upper surface 2141 faces the joint surface 2312 of the heat dissipation device 231, and the side surface 2142 faces the on-board components 213. Two adjacent sides of the annular insulation component 232 respectively contact the side surface 2142 of the annular frame 214 and the on-board components 213.

In some embodiments, the thermal interface material 22 may be a metal that can undergo a phase change between a liquid state and a solid state, and has high thermal conductivity and high electrical conductivity.

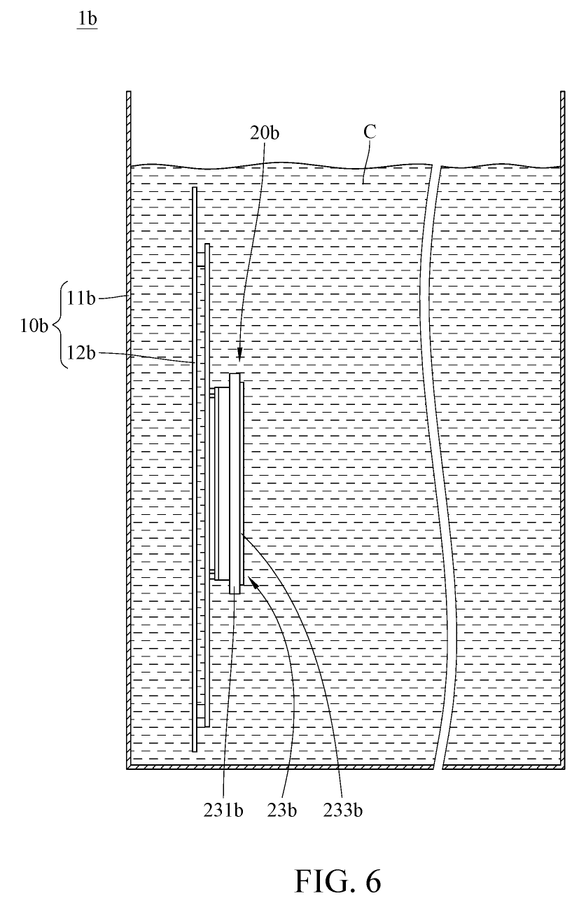

In some embodiments, the heat dissipation device 231 may be a cold plate, allowing a working fluid to flow therethrough, and the heat dissipation device 231 may be provided with a fin structure therein, but the disclosure is not limited thereto. In some other embodiments, the heat dissipation device may be a heat sink with a fin structure that does not allow the working fluid to flow therethrough. In some embodiments, the heat dissipation device may be a boiler plate ( e.g., a boiler plate described in FIG. 6).

In some embodiments, the thermally coupling surface 2311 may be coplanar with the joint surface 2312 of the heat dissipation device 231, but the disclosure is not limited thereto. In some other embodiments, the thermally coupling surface may not be coplanar with the joint surface of the heat dissipation device.

In some embodiments, the heat dissipation device 231 may have a groove 2313. The groove 2313 separates the thermally coupling surface 2311 and the joint surface 2312. An orthogonal projection of the groove 2313 is entirely located on the annular frame 214. In other words, the groove 2313 is located directly above the annular frame 214. The groove 2313 is configured to accommodate a part of the thermal interface material 22.

In some embodiments, the groove 2313 may be in an annular shape, but the disclosure is not limited thereto. In some other embodiments, the groove may not be in the annular shape, the number of the grooves may be multiple, and these grooves may be annularly arranged.

In some embodiments, the annular insulation component 232 has elasticity, and the annular insulation component 232 is, for example, made of resin. In some embodiments, the annular insulation component 232 is pre-fixed to the joint surface 2312 of the heat dissipation device 231 before the heat dissipation assembly 23 is assembled onto the motherboard 21, where the joint surface 2312 of the heat dissipation device 231 may be a flat surface.

Next, the process of assembling the heat dissipation assembly 23 onto the motherboard 21 will be described. First, as shown in FIG. 2, the thermal interface material 22 is placed on the heat source 212 and the upper surface 2141 of the annular frame 214, where the thermal interface material 22 at this stage can be in the liquid state or the solid state.

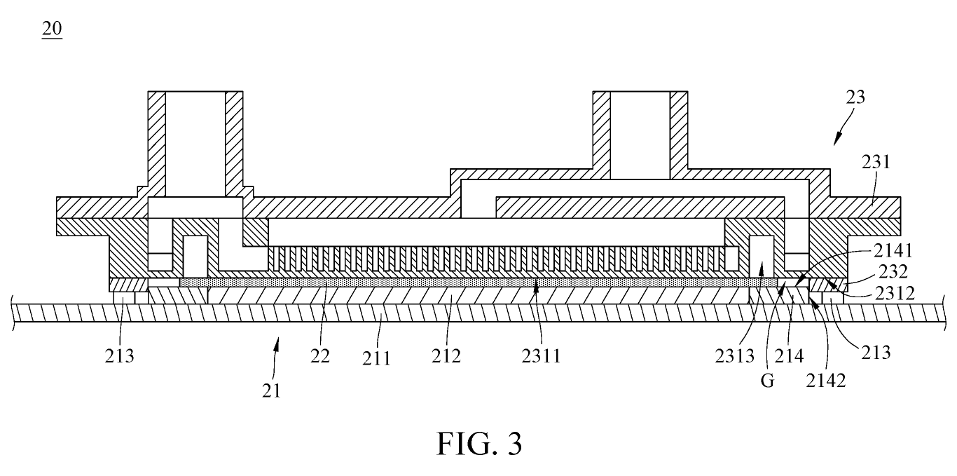

Then, referring to FIG. 3, FIG. 3 shows the heat dissipation assembly 23 is placed on the motherboard 21 of the motherboard module 20 according to some embodiments of the disclosure. The structural features of FIG. 3 can be applied to other embodiments of the disclosure. As shown in FIG. 3, the heat dissipation assembly 23 is placed on the motherboard 21, such that the thermally coupling surface 2311 of the heat dissipation device 231 contacts one side of the thermal interface material 22 located farther away from the heat source 212, and two adjacent sides of the annular insulation component 232 respectively contact the side surface 2142 of the annular frame 214 and the on-board components 213. At this moment, the heat dissipation device 231 is in an uncompressed state, and the thermal interface material 22 in the liquid state or the solid state is not compressed and is spaced apart from the annular insulation component 232 so as to form a gap G therebetween. If the thermal interface material 22 is in the solid state at this stage, the thermal interface material 22 is then heated to become the liquid state.

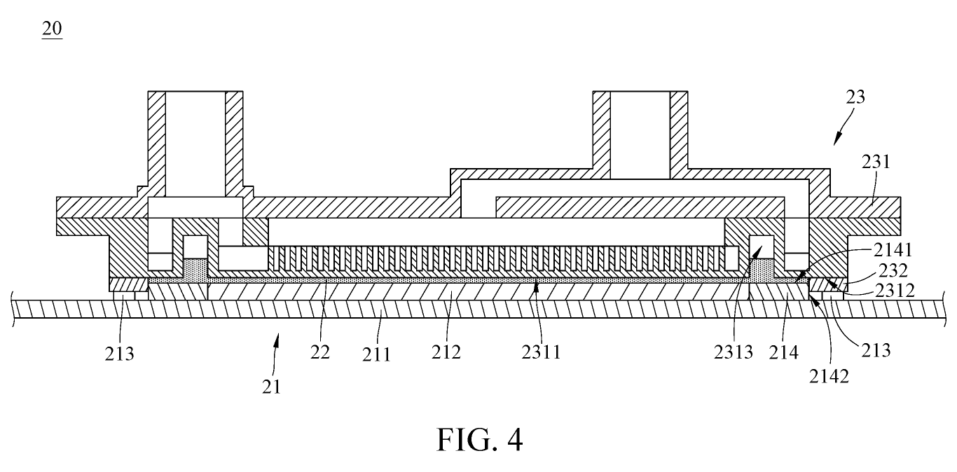

Then, referring to FIG. 4, FIG. 4 shows the thermal interface material 22 flows after the heat dissipation assembly 23 placed on the motherboard 21 is pressed downward according to some embodiments of the disclosure. The structural features of FIG. 4 can be applied to other embodiments of the disclosure. As shown in FIG. 4, an external force is applied to the heat dissipation device 231 in a direction toward the heat source 212, causing the heat dissipation device 231 to move and switch from the uncompressed state to a compressed state. At this moment, a part of the liquid thermal interface material 22 enters the gap G (as shown in FIG. 3) and the groove 2313, and the thermal interface material 22 is separated from the on-board components 213 by the annular insulation component 232. In this way, the process of assembling the heat dissipation assembly 23 onto the motherboard 21 is completed.

In the above embodiments, the annular insulation component 232 is fixed on the joint surface 2312 around the thermally coupling surface 2311 of the heat dissipation device 231, and the annular insulation component 232 contacts the on-board components 213 around the heat source 212 of the motherboard 21. By this configuration, the annular insulation component 232 avoids the problem of insufficient sealing between the heat dissipation device 231 and itself due to inconsistent heights of the on-board components 213. Therefore, it ensures that the annular insulation component 232 can effectively limit the thermal interface material 22 so as to separate the thermal interface material 22 from the on-board components 213.

Additionally, when the heat dissipation device 231 in the uncompressed state, the thermal interface material 22 is spaced apart from the annular insulation component 232 so as to form a gap G therebetween, and the heat dissipation device 231 has the groove 2313. This configuration allows the thermal interface material 22 to flow outward after the heat dissipation device 231 is pressed downward, reducing the risk of the thermal interface material 22 breaking through the limitation of the annular insulation component 232.

On the other hand, the groove 2313 of the heat dissipation device 231 separates the thermally coupling surface 2311 and joint surface 2312, and the orthogonal projection of the groove 2313 is entirely located on the annular frame 214. By this configuration, the position of the groove 2313 ensures that it does not sacrifice the contact area between the heat source 212 and the thermally coupling surface 2311 of the heat dissipation device 231, which avoids excessively affect the heat exchange efficiency between the heat source 212 and the heat dissipation device 231. In some embodiments, the orthogonal projection of the groove 2313 is arranged to surround an outer boundary of the heat source 212. In the embodiment shown in FIG. 4, the orthogonal projection of the groove 2313 is arranged entirely offsetting a top surface of the heat source 212.

It should be noted that the orthogonal projection of the groove 2313 is not limited to being entirely located on the annular frame 214. In some other embodiments, if the arrangement of the groove does not excessively affect the heat exchange efficiency between the heat source and the heat dissipation device, the orthogonal projection of the groove may be partially or entirely located on the heat source. In other words, the orthogonal projection of the groove may be partially located on the annular frame, or the orthogonal projection of the groove may not be located on the annular frame at all. On the other hand, the annular frame 214 is an optional component and may be omitted in some other embodiments.

The configuration of the gap G and the groove 2313 mentioned above is optional. In some other embodiments, either the gap or the groove may be omitted or selected according to actual requirements.

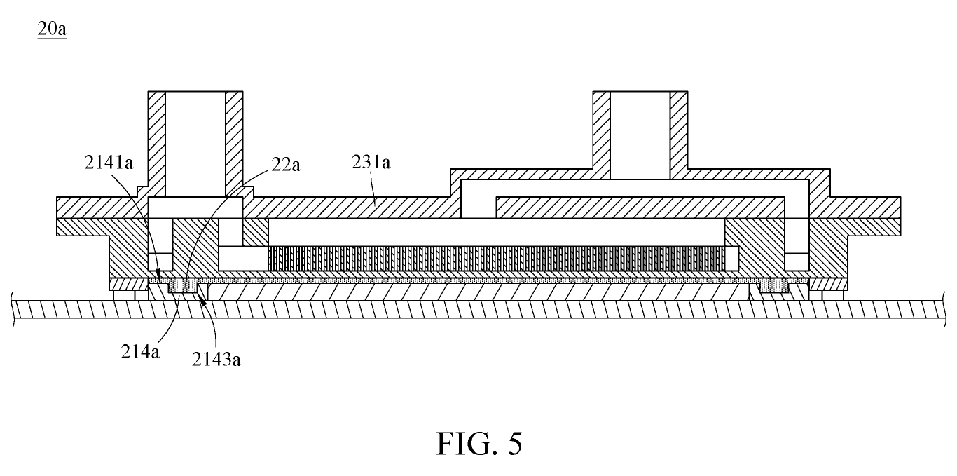

Then, referring to FIG. 5, FIG. 5 is a cross-sectional view of a motherboard module 20a according to some embodiments of the disclosure. The structural features of FIG. 5 can be applied to other embodiments of the disclosure.

The motherboard module 20a in FIG. 5 is similar to the motherboard module 20 in FIG. 4. The differences between them are mainly described in the following paragraph, and the similar parts will not be repeated hereinafter.

In the embodiment of FIG. 5, a groove 2143a is provided on an annular frame 214a instead of a heat dissipation device 231a, wherein the groove 2143a is recessed from an upper surface 2141a of the annular frame 214a and is configured to accommodate a part of a thermal interface material 22a.

Then, referring to FIG. 6, FIG. 6 is a partial cross-sectional view of an electronic device 1b according to some embodiments of the disclosure. The structural features of FIG. 6 can be applied to other embodiments of the disclosure.

The electronic device 1b in FIG. 6 is similar to the electronic device 1 in FIG. 1. The differences between them are mainly described in the following paragraph, and the similar parts will not be repeated hereinafter.

In the embodiment shown in FIG. 6, an accommodation assembly 10b includes a tank 11b and a support component 12b. The tank 11b is configured to accommodate a coolant C. The support component 12b, such as a tray or a bracket, is fixed in the tank 11b. The motherboard module 20b is disposed on the support component 12b. In other words, the motherboard module 20b is accommodated in the tank 11b via the support component 12b, such that the motherboard module 20b is at least partially immersed in the coolant C.

In one embodiment, a heat dissipation device 231b of a heat dissipation assembly 23b in the motherboard module 20b may be a boiler plate, which is provided with a boiling enhancement structure 233b. The function of the boiling enhancement structure 233b is to increase the nucleation sites for bubbles, resulting in the generation of more boiling bubbles per unit time, as well as increasing the surface area in contact with the coolant C. Although the boiling enhancement structure 233b shown in FIG. 6 is simplified as a sheet, in practice, the boiling enhancement structure 233b may include at least one of the following: a mesh metal structure, a flat fin structure, a pin fin structure, or a sintered metal structure.

According to the heat dissipation assembly, the motherboard module and the electronic device as discussed in the above embodiments, the annular insulation component is fixed on the joint surface around the thermally coupling surface of the heat dissipation device, and the annular insulation component contacts the on-board components around the heat source of the motherboard. By this configuration, the annular insulation component avoids the problem of insufficient sealing between the heat dissipation device and itself due to inconsistent heights of the on-board components. Therefore, it ensures that the annular insulation component can effectively limit the thermal interface material so as to separate the thermal interface material from the on-board components.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A motherboard module, comprising:
a motherboard, comprising a circuit board, a heat source and a plurality of on-board components, wherein the heat source and the plurality of on-board components are disposed on the circuit board, and the plurality of on-board components are located around the heat source;
a thermal interface material; and
a heat dissipation assembly, comprising:
a heat dissipation device, having a thermally coupling surface and a joint surface, wherein the thermally coupling surface is thermally coupled to the heat source of the motherboard via the thermal interface material, and the joint surface is located around the thermally coupling surface; and
an annular insulation component, fixed to the joint surface and configured to contact the plurality of on-board components located around the heat source of the motherboard, wherein the annular insulation component surrounds and limits the thermal interface material to separate the thermal interface material from the plurality of on-board components.

2. The motherboard module according to claim 1, wherein the heat dissipation device is movable along a direction toward the heat source by an external force so as to switch from a uncompressed state to a compressed state; when the heat dissipation device is in the uncompressed state, the thermal interface material is spaced apart from the annular insulation component so as to form a gap therebetween; when the heat dissipation device is in the compressed state, the thermal interface material enters the gap.

3. The motherboard module according to claim 1, wherein the thermal interface material, when in a liquid state and uncompressed or in a solid state, is spaced apart from the annular insulation component so as to form a gap therebetween; when the thermal interface material is in the liquid state and compressed, or undergoes a phase change from the solid state to the liquid state, the thermal interface material enters the gap.

4. The motherboard module according to claim 1, wherein the motherboard further comprises an annular frame, the annular frame is mounted on the circuit board, the annular frame is in contact with an outer edge of the heat source and located between the heat source and the plurality of on-board components, the annular frame has an upper surface and a side surface located adjacent to each other, the upper surface faces the joint surface of the heat dissipation device, the side surface faces the plurality of on-board components, two adjacent sides of the annular insulation component are respectively in contact with the side surface of the annular frame and the plurality of on-board components.

5. The motherboard module according to claim 4, wherein the annular frame has a groove, the groove is recessed from the upper surface, and the groove is configured to accommodate a part of the thermal interface material.

6. The motherboard module according to claim 4, wherein the heat dissipation device has a groove, the groove separates the thermally coupling surface and the joint surface, an orthogonal projection of the groove is entirely located on the annular frame, and the groove is configured to accommodate a part of the thermal interface material.

7. The motherboard module according to claim 5, wherein the groove is in an annular shape.

8. The motherboard module according to claim 1, wherein the thermally coupling surface is coplanar with the joint surface.

9. The motherboard module according to claim 1, wherein the heat dissipation device is a cold plate or a boiler plate.

10. A heat dissipation assembly, configured to be thermally coupled to a heat source of a motherboard via a thermal interface material, the heat dissipation assembly comprising:
a heat dissipation device, having a thermally coupling surface and a joint surface, wherein the thermally coupling surface is configured to be thermally coupled to the heat source of the motherboard via the thermal interface material, and the joint surface is located around the thermally coupling surface; and
an annular insulation component, fixed to the joint surface and configured to contact a plurality of on-board components located around the heat source of the motherboard, wherein the annular insulation component is configured to surround and limit the thermal interface material to separate the thermal interface material from the plurality of on-board components.

11. The heat dissipation assembly according to claim 10, wherein the thermally coupling surface is coplanar with the joint surface.

12. The heat dissipation assembly according to claim 10, wherein the heat dissipation device has a groove, the groove separates the thermally coupling surface and the joint surface, and the groove is configured to accommodate a part of the thermal interface material.

13. The heat dissipation assembly according to claim 12, wherein the groove is in an annular shape.

14. The heat dissipation assembly according to claim 10, wherein the heat dissipation device is a cold plate or a boiler plate.

15. An electronic device, comprising:
an accommodation assembly; and
at least one motherboard module, disposed in the accommodation assembly and comprising:
a motherboard, comprising a circuit board, a heat source and a plurality of on-board components, wherein the heat source and the plurality of on-board components are disposed on the circuit board, and the plurality of on-board components are located around the heat source;
a thermal interface material; and
a heat dissipation assembly, comprising:
a heat dissipation device, having a thermally coupling surface and a joint surface, wherein the thermally coupling surface is thermally coupled to the heat source of the motherboard via the thermal interface material, and the joint surface is located around the thermally coupling surface; and
an annular insulation component, fixed to the joint surface and configured to contact the plurality of on-board components located around the heat source of the motherboard, wherein the annular insulation component surrounds and limits the thermal interface material to separate the thermal interface material from the plurality of on-board components.

16. The electronic device according to claim 15, wherein the heat dissipation device is movable along a direction toward the heat source by an external force so as to switch from a uncompressed state to a compressed state; when the heat dissipation device is in the uncompressed state, the thermal interface material is spaced apart from the annular insulation component so as to form a gap therebetween; when the heat dissipation device is in the compressed state, the thermal interface material enters the gap.

17. The electronic device according to claim 15, wherein the thermal interface material, when in a liquid state and uncompressed or in a solid state, is spaced apart from the annular insulation component so as to form a gap therebetween; when the thermal interface material is in the liquid state and compressed, or undergoes a phase change from the solid state to the liquid state, the thermal interface material enters the gap.

18. The electronic device according to claim 15, wherein the motherboard further comprises an annular frame, the annular frame is mounted on the circuit board, the annular frame is in contact with an outer edge of the heat source and located between the heat source and the plurality of on-board components, the annular frame has an upper surface and a side surface located adjacent to each other, the upper surface faces the joint surface of the heat dissipation device, the side surface faces the plurality of on-board components, two adjacent sides of the annular insulation component are respectively in contact with the side surface of the annular frame and the plurality of on-board components.

19. The electronic device according to claim 18, wherein the annular frame has a groove, the groove is recessed from the upper surface, and the groove is configured to accommodate a part of the thermal interface material.

20. The electronic device according to claim 18, wherein the heat dissipation device has a groove, the groove separates the thermally coupling surface and the joint surface, an orthogonal projection of the groove is entirely located on the annular frame, and the groove accommodates a part of the thermal interface material.

21. The electronic device according to claim 19, wherein the groove is in an annular shape.

22. The electronic device according to claim 15, wherein the thermally coupling surface is coplanar with the joint surface.

23. The electronic device according to claim 15, wherein the accommodation assembly comprises a tank, the tank is configured to accommodate a coolant and the at least one motherboard module, such that the at least one motherboard module is at least partially immersed in the coolant.

24. The electronic device according to claim 15, wherein the accommodation assembly comprises a rack, and the rack is configured to accommodate the at least one motherboard module.
